(19) United States
(12) Patent Application Publication
(10) Pub. No.: US 2012/0223616 A1
(43) Pub. Date: Sep. 6, 2012

(54) Surface Acoustic Wave Resonator

(76) Inventors: Roderick Wayland Bates, Singapore (SG); Xavier Golay, London (GB); Changtong Yang, Singapore (SG)

(21) Appl. No.: 13/504,387

(22) PCT Filed: Oct. 29, 2010
(86) PCT No.: PCT/SG2010/000418

§ 371 Date: Apr. 26, 2012

(30) Foreign Application Priority Data
Oct. 30, 2009 (SG) 200907247-1

(51) Int. Cl. H01L 41/02; H03H 3/08

(52) U.S. Cl. 310/313 A; 29/25.35

(57) ABSTRACT

According to embodiments of the present invention, a surface acoustic wave resonator is provided. The surface acoustic wave resonator includes: a first electrode and a second electrode arranged in a first layer; a piezoelectric material formed in a second layer adjacent to the first layer; wherein the piezoelectric material is electrically coupled to the first electrode and the second electrode; and wherein the first layer is free of the

### CROSS-REFERENCE TO RELATED APPLICATIONS

This application claims the benefit of priority of Singapore' application No. 200907247-1, filed 30 Oct. 2009, the content of it being hereby incorporated by reference in its entirety for all purposes.

### TECHNICAL FIELD

Various embodiments relate to a surface acoustic wave resonator and a method for manufacturing a surface acoustic wave resonator.

### BACKGROUND

Crystal resonators have been introduced since the beginning of the previous century and continue to provide the essential reference clock for all electronic components. With the decades of developments, a whole portfolio of products have been realized for generating accurate reference clock such as resonators, fixed frequency oscillators, voltage controlled oscillators, and programmable oscillators. Coupled with the use of integrated circuit (IC), all the oscillators can be compensated electronically for temperature drift. With a stable and miniaturized clock generator, portable communication products such as mobile phones, Bluetooth and WiFi devices can be introduced commercially at convenient sizes and at reasonable prices. Recent developments have attempted to fabricate smaller resonators, some of which involve processes compatible with IC.

Developments have been made to use microstructures within the regime of resonators, by exploiting the structures in flexural mode or contour mode vibration (Wang K. et al., “VHF Free-Free Beam High-Q Micromechanical Resonators”, J. MEMS 2000, 9(3), 347-360; Clark J. R. et al., “High-Q UHF Micromechanical Radial-Contour Mode Disk Resonators”, J. MEMS 2005, 14(6), 1298-1310). For these microstructures, electrostatic force is used to drive the microstructures at certain resonance mode. FIG. 1 shows the SEM images of electrostatic driven micro resonators of the prior art. FIG. 1(a) shows a clamped-clamped beam resonator structure 100 and FIG. 1(b) shows a free-free beam resonator structure. 102 operating at the flexural mode of the structures while FIG. 1(c) shows a disk resonator 104 operating at the contour mode to achieve even higher frequency. However, the coupling coefficient of these microstructures is weak and generally dominated by the minimum or narrow gap in the design fabrication. In addition, the microstructures can only achieve resonance in a high vacuum environment due to the serious air damping caused by the narrow gap.

Another conventional actuation mechanism is to use piezoelectric material, such as that for bulk acoustic wave (BAW) resonators. For these resonators, patterned electrode is used to excite the piezoelectric material and to force the structures to operate at a certain resonance mode. FIG. 2 shows the SEM images of bulk acoustic wave (BAW) resonators, with structures vibrating at the contour mode or the flexural mode, of the prior art (Piazza G. et al., “Single-Chip Multiple-Frequency ALN MEMS Filters Based on Contour-Mode Piezoelectric Resonators”, J. MEMS 2007, 16(2), 319-328). FIG. 2(a) shows a ring type structure 200 while FIG. 2(b) shows a plate flexural type structure 202. For the BAW resonators of FIGS. 2(a) and 2(b), the resonant frequency is defined by the shape of the resonator structures. As the impedance of the resonators is inversely proportional to the electrode area, tuning the impedance of the resonators would require altering the electrode area, and hence the resonator structures. However, this would also change the resonant frequency of the resonator structures. Therefore, there is a challenge in trying to tune the impedance without substantially changing the resonant frequency. Further, while BAW resonators may be integrated with IC, batch production of BAW resonators can only fabricate BAW resonators for operation at one frequency for each batch (ie. each and every BAW resonator in the same batch has the same resonant frequency).

Film bulk acoustic resonator (FBAR) is another type of resonator conventionally used. FIGS. 3(a) and 3(b) show, respectively, a cross-sectional view of a film bulk acoustic resonator (FBAR) 300 and a measurement plot 302 with a photo 304 of the FBAR 300, of the prior art (Dubois M. et al., “Monolithic Above-IC Resonator Technology for Integrated Architectures in Mobile and Wireless Communication”, JSSC 2006, 41(1), 7-16). For this resonator, the piezoelectric material itself vibrates at the thickness mode, meaning that the material thickness is an integer multiple of the wavelength of the acoustic wave generated. This mechanism can largely increase the coupling coefficient and achieve larger than 1000 quality factor even in the gigahertz (GHz) range in atmosphere. The process itself is intrinsically IC compatible. For the FBAR of FIG. 3, the resonant frequency is defined by the thickness of the film. Therefore, the impedance of the FBAR may be tuned by altering the electrode area, and hence the resonator structures, without changing the resonant frequency of the FBAR, compared to the BAW resonators of FIGS. 2(a) and 2(b). However, batch production of FBARs can only fabricate FBARs for operation at one frequency for each batch (ie. each and every FBAR in the same batch has the same resonant frequency), due to the similar thin film deposition process used in the same batch.

Recent developments of resonators have also, included fabrication of surface acoustic wave (SAW) devices with reflectors on top of CMOS processes (Nordin N. A. et al., “Modeling and Fabrication of CMOS Surface Acoustic Wave Resonators”, MTT 2007, 55(5), 992-1001; Nordin N. A. et al., “Design and Implementation of a 1 GHz CMOS Resonator Utilizing Surface Acoustic Wave”, ISCAS 2006). FIG. 4(a) shows a cross-sectional view of a CMOS surface acoustic wave (SAW) resonator 400 while FIG. 4(b) shows an SEM image 402 of a CMOS SAW resonator, of the prior art. The process utilizes the metal layers from the CMOS process in combination with zinc oxide (ZnO) deposition and etching to fabricate an SAW device on CMOS, which can be integrated with oscillator circuits. However, the film thickness is much smaller than the wavelength, thereby causing the energy to penetrate into the substrate. The measured quality factor can only reach about 200. Besides, much of the device area is occupied by the reflectors present in the device.

Conventional resonators, including SAW resonators; may have one or more of the following disadvantages: (i) low coupling efficiency, (ii) high DC biasing, (iii) requirement of reflectors and the associated large device area (iv) high level of vacuum packaging, (v) one resonant frequency for each batch processing, (vi) requirement of conductors, and (vii) incompatibility for operation at the gigahertz (GHz) frequency range or higher modes of harmonic frequency. In addition, conventional SAW resonators have been fabricated with their electrodes buried underneath the piezoelectric material. Surface acoustic wave (SAW) devices have generally been reliable, inexpensive and provided a simple way of fabricating high frequency resonators. Using a single mask to define the electrodes of the devices, a variety of quality factors and resonant frequencies may be defined. However, reflectors are conventionally required to reduce the energy loss and these reflectors occupy a huge amount of area on the devices, and in particular for devices for operation at low ‘frequencies. In addition, the inability to deposit sufficiently thick piezoelectric material also creates a barrier to integrate SAW devices with integrated circuits.

### SUMMARY

According to an embodiment, a surface acoustic, wave resonator is provided. The surface acoustic wave resonator may include: a first electrode and a second electrode arranged in a first layer; a piezoelectric material formed in a second layer adjacent to the first layer; wherein the piezoelectric material is electrically coupled to the first electrode and the second electrode; and wherein the first layer is free of the piezoelectric material.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows SEM images of electrostatic driven micro resonators of prior art.

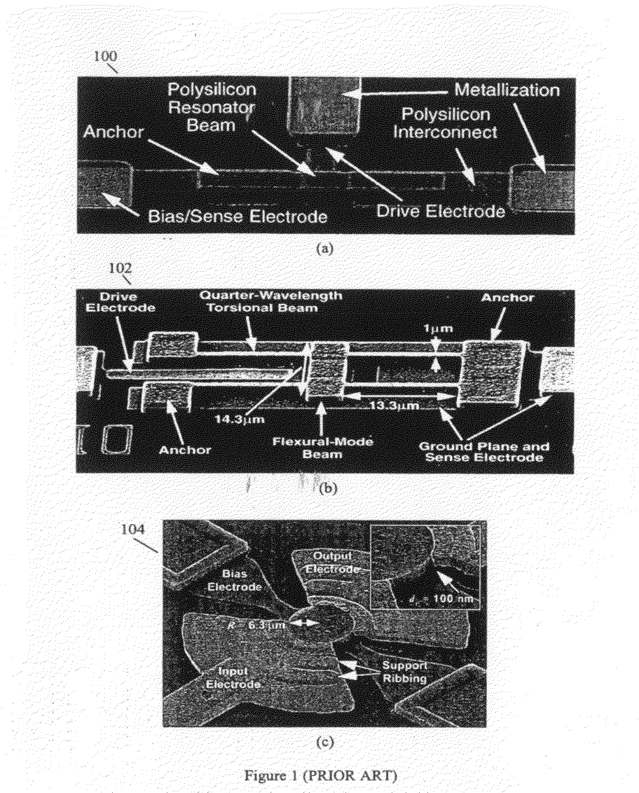

FIG. 2 shows SEM images of bulk acoustic wave (BAW) resonators of prior art.

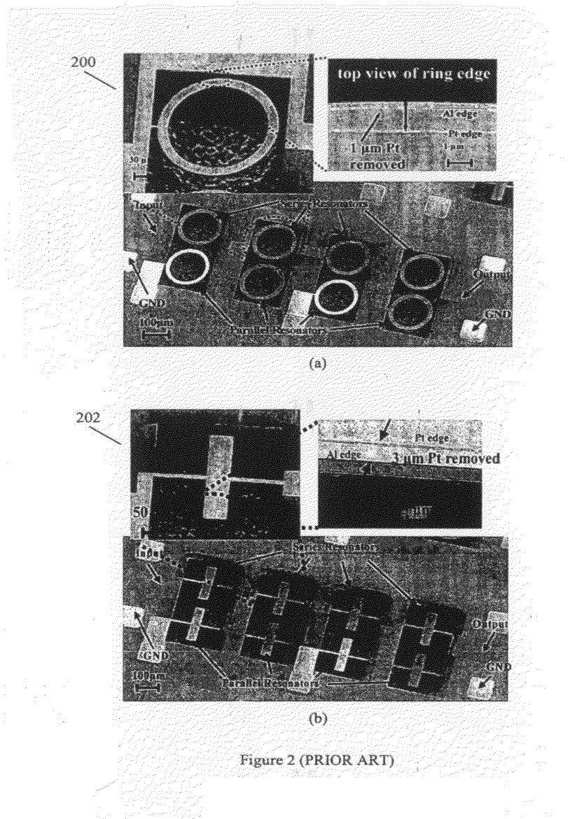

FIG. 3 shows a film bulk acoustic resonator (FBAR) of prior art.

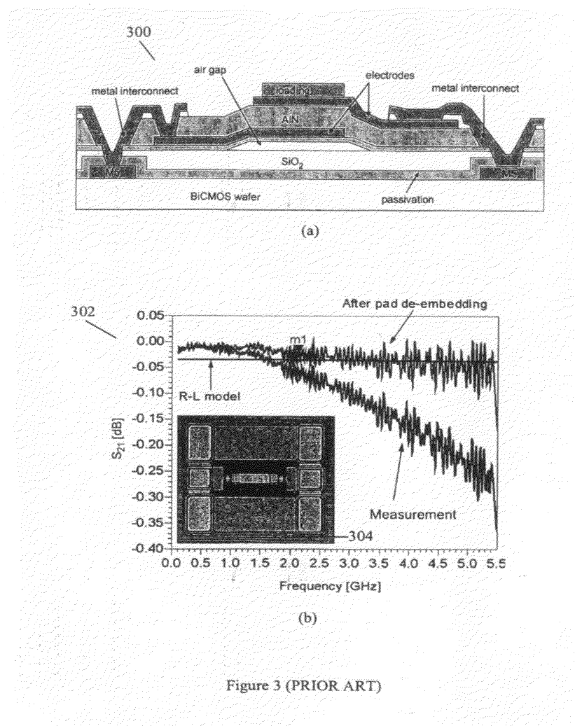

FIG. 4 shows a cross-sectional view and an SEM image of CMOS surface acoustic wave (SAW) resonators of prior art.

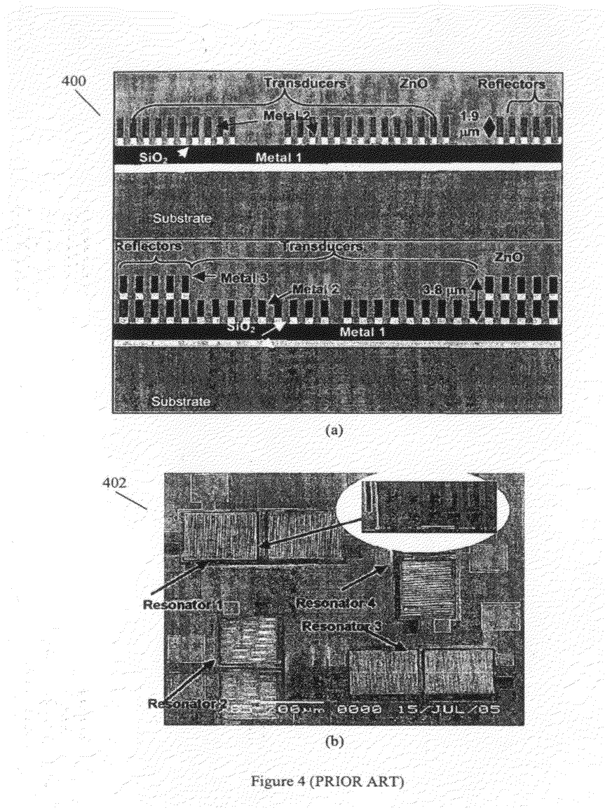

FIG. 5 illustrates the propagation of surface acoustic waves.

FIGS. 6A-6D show schematic views of a surface acoustic wave resonator, according to one embodiment.

FIG. 6E shows a schematic top view of a surface acoustic wave resonator, according to one embodiment.

FIG. 6F shows SEM images of electrodes of the surface acoustic wave resonators, according to various embodiments.

FIG. 6G shows a schematic top view of a pair of electrodes with a concentric-circular pattern, according to one embodiment.

FIG. 7 shows a cross-sectional view of a surface acoustic wave resonator, according to one embodiment.

FIG. 8 shows a flow chart illustrating a method of forming a surface acoustic wave resonator, according to various embodiments.

FIGS. 9A to 9F show cross-sectional views of a fabrication process to manufacture a surface acoustic wave resonator, according to various embodiments.

FIGS. 10A to 10D show cross-sectional views of a fabrication process to manufacture a surface acoustic wave resonator, according to various embodiments.

FIG. 11 shows simulation data of a surface acoustic wave resonator of one embodiment.

FIG. 12 shows a plot of resonant mode shape and impedance frequency response for the embodiment of FIG. 11.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Various embodiments may provide a surface acoustic wave (SAW) resonator or device with relatively improved performance and an efficient use of the device area, without or with reduced at least some of the associated disadvantages of the current resonators or devices.

Various embodiments may provide an SAW resonator and a method of forming the SAW resonator that address the integration issues of conventional resonators, while also eliminating the need for a reflector or reflectors for the SAW resonator (ie. a reflector-less design or a reflector-less SAW resonator). Accordingly, the absence of reflectors may reduce the area of the device and may lead to relatively smaller resonators and devices.

Various embodiments may provide an SAW resonator including a piezoelectric material or a piezoelectric structure that may generate and propagate surface acoustic waves. The piezoelectric material or the piezoelectric structure incorporating a piezoelectric material may function as a surface acoustic wave medium. The piezoelectric material or structure may have substantially free boundary at the edges. The free boundary at the edges or in other words, the free edges, may provide a similar function as that of the reflectors in conventional resonators.

Various embodiments may provide an SAW resonator where the piezoelectric material or piezoelectric structure is substantially configured to levitate at a distance from a substrate of the resonator, for example on or above the substrate, such that energy loss through the substrate may be minimized. The levitation of the piezoelectric material or structure therefore provides a substantially floating surface acoustic wave (FSAW) structure. Levitating the piezoelectric material or structure may provide free boundary at the piezoelectric material or structure, and therefore the need for reflectors is eliminated and an increased quality factor may be achieved. In addition, various embodiments may provide appropriately positioned supports or micro-supporting anchor structures to minimize energy loss through the substrate.

Various embodiments may provide a radio frequency microelectromechanical systems (RFMEMS) resonator. Various embodiments may provide a microelectromechanical systems (MEMS) fabrication method to fabricate a surface acoustic wave (SAW) resonator or device. The fabrication of the SAW resonators may be carried out in a batch operation to advantageously reduce the production cost. In addition, during the fabrication process, various embodiments may provide flexibility to tune the resonant frequency of the SAW resonators fabricated. Various embodiments may provide a process compatible with IC integration and a cost-effective process for fabricating SAW resonators on IC processes.

Various embodiments may provide a batch processing method with a relatively large flexibility to fabricate SAW resonators with different resonant frequencies in the same batch. In other words, the batch processing of various embodiments may allow a plurality of SAW resonators to be fabricated in the same batch, where each SAW resonator may have a different resonant frequency.

Various embodiments may provide an SAW resonator and a method of fabricating an SAW resonator that may allow relatively easy determination of the resonant frequency of the SAW resonator, by determining the phase velocity: and the wavelength of the surface acoustic wave. The phase velocity may be determined based on the properties of the materials or compositions of materials, such as the density and thickness of the piezoelectric material and the interdigital transducer that excites or generates the surface acoustic wave. The wavelength may be determined by the period of the interdigital transducer. In various embodiments, the period of the interdigital transducer may be defined by a lithography process.

Various embodiments may provide an SAW resonator or device that may operate in atmosphere with reasonably acceptable quality factor and that does not require a vacuum environment for operation. The quality factor or Q factor describes the damping of an oscillator or resonator, or equivalently, characterizes a resonator's bandwidth relative to its center or resonant frequency. A higher Q factor generally indicates a lower rate of energy loss relative to the stored energy of the oscillator. Various embodiments may provide SAW resonators with a quality factor of about 700. In further embodiments, the SAW resonators may have a quality factor in the range of about 400 to 1000, for example a range of about 400 to 700 or a range of about 700 to 1000, such that the quality factor may be about 400, about 500, about 600, about 700, about 800, about 900 or about 1000. Various embodiments may provide gigahertz (GHz) frequency SAW resonators with a relatively high quality factor that may offer relatively lower power and relatively lower phase noise oscillators.

Various embodiments may provide a clock generation system or circuit, for example in the form of a chip, including the combination of the SAW resonators or devices with IC. As the size of the chip is generally relatively small, batch production of the chips may be carried out to reduce the production cost. In addition, during the fabrication process, various embodiments may provide flexibility to tune the resonant frequency of the SAW resonators, for example, to fabricate a plurality of SAW resonators in the same batch, where each SAW resonator may have a different resonant frequency. Furthermore, such a production may allow the integration of the clock generation system with other systems, such as radio frequency (RF) transceivers, for added functionalities. Various embodiments may provide a surface acoustic wave (SAW) resonator or device for use as a clock or timing chip and also as a local oscillator for radio frequency (RF) systems.

Various embodiments may provide an SAW resonator and a method of forming an SAW resonator that are CMOS compatible.

Various embodiments may provide a fabrication process or processing operations that use two masks, such as for forming and patterning electrodes and forming a piezoelectric structure making up an SAW resonator. Further embodiments may provide a single mask processing operation to define a piezoelectric material for an SAW resonator on IC processes for IC integration.

Various embodiments may advantageously provide SAW resonators or devices with a reflector-less design (ie absence of reflectors), a reduced device area or size, an impedance matching capability and resonators that may operate in atmosphere, without requiring vacuum packaging and resonators with no requirement for relatively high voltage DC biasing. In various embodiments, the impedance of the SAW resonator is inversely proportional to the electrode area or the area of the interdigital transducer (IDT) including the electrode or electrodes. As known in the art, generally, the impedance of an RF circuit design is set at 50 ohm (50Ω). Therefore, the impedance of the SAW resonator should be provided to: match 50Ω, by varying the electrode area, in order to facilitate an effective energy transfer between the SAW resonator and the RF circuit.

In various embodiments, the surface acoustic wave (SAW) resonator may include an interdigital transducer (IDT) and a piezoelectric material or a piezoelectric structure incorporating a piezoelectric material. The IDT may include a pair of electrodes and may be formed of metal. The surface acoustic wave resonator may be configured to have a structure where the IDT is arranged in a first layer and the piezoelectric material or structure is formed in a second layer adjacent to the first layer. The first layer may also be referred to as the metal layer while the second layer may also be referred to as the piezoelectric material layer. The IDT and the piezoelectric material or structure may form a resonating microstructure where the material or structure may be electrically coupled to the IDT or the pair of electrodes of the IDT such that the IDT may excite a surface acoustic wave to propagate through or on the surface of the piezoelectric material or structure.

In various embodiments, the piezoelectric material or piezoelectric structure may be substantially configured to levitate at a distance from a substrate of the resonator, for example on or above the substrate. In various embodiments, each of the pair of electrodes may be substantially configured to levitate at a distance from a substrate of the resonator, for example on or above the substrate.

In various embodiments, the first layer of the IDT including the pair of electrodes may be free of piezoelectric material or the piezoelectric structure. In various embodiments, the piezoelectric material or structure may be formed only in the second layer. In various embodiments, each of the pair of electrodes may be combed-shaped and the pair of electrodes may be arranged in an interdigitated pattern or structure. In various embodiments, providing a separate first layer comprising an IDT and a second layer comprising a piezoelectric material may provide relatively greater flexibility in tuning the phase velocity of the surface acoustic wave, by varying the density and thickness of the IDT and the piezoelectric material.

In various embodiments, a substantial surface of the piezoelectric material or the piezoelectric structure may be electrically coupled to a substantial surface of the IDT or a substantial surface of the interdigitated pair of electrodes such that an electrical signal applied to the interdigitated pair of electrodes may excite or generate a surface acoustic wave to propagate through or on the surface of the piezoelectric material or the piezoelectric structure.

In further embodiments, the surface acoustic wave resonator may include a plurality of IDTs arranged on a single metal layer or a plurality of IDTs arranged on a plurality of metal layers. The plurality of IDTs may have a corresponding plurality of piezoelectric materials.

In the context of various embodiments, the term “surface acoustic wave” may mean an acoustic wave traveling along the surface of a material exhibiting elasticity, for example a piezoelectric material, with an amplitude that typically decays exponentially with depth into the material. As the acoustic wave propagates through or on the surface of the material, any changes to the characteristics of the propagation path may affect the velocity and/or amplitude of the wave. In isotropic solids, the surface particles move in ellipses in planes normal to or parallel to the surface and parallel to the direction of propagation. At the surface and at shallow depths, this motion is retrograde. Particles deeper in the material move in smaller ellipses with an eccentricity that changes with depth. At greater depths, the particle motion becomes prograde. The depth of significant displacement in the solid is approximately equal to the wavelength of the surface acoustic wave.

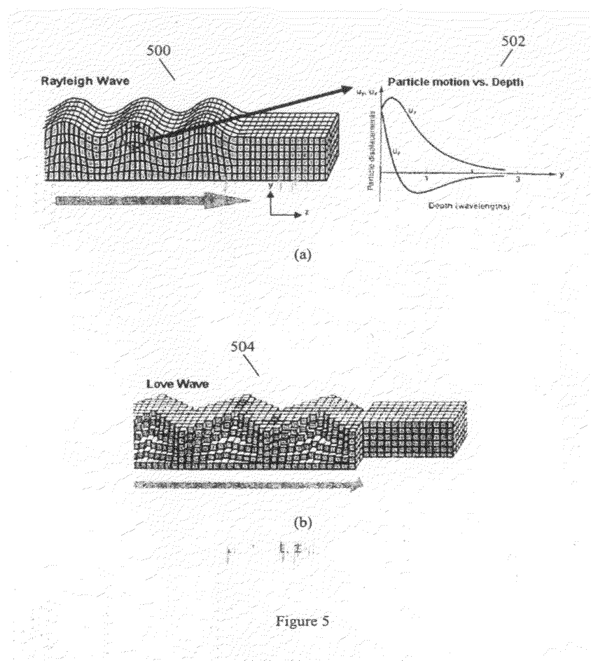

FIG. 5 illustrates the surface acoustic waves and their propagations. FIG. 5(a) shows a Rayleigh wave 500 and a plot 502 of the relationship between the particle motion and depth associated with the Rayleigh wave 500. For the Rayleigh wave 500, particles move in the vertical-shear mode. FIG. 5(b) shows a Love wave 504, where the particles move in the horizontal-shear mode. Generally, the phase velocity of the Love wave 504 is slightly faster than the Rayleigh wave 500. As the surface acoustic waves are confined near the surface, their in-plane amplitude when generated by a point source decays as \sqrt{1/r}, where r is the radial distance. Therefore, surface waves decay more slowly with distance than do bulk waves, which spread out in three dimensions from a point source.

In the context of various embodiments, the term “resonator” may mean a device or a system that exhibits resonance, where the device may oscillate or resonate at relatively larger amplitudes at particular frequencies, known as its resonant frequencies, compared to the amplitudes of the oscillations at non-resonant frequencies. A resonator may be used to excite or generate waves such that a surface acoustic wave resonator may be used to generate surface acoustic waves in a medium. The waves generated may have specific frequencies.

In the context of various embodiments, the term “piezoelectric material”, as known in the art, may mean a material that may produce a voltage in response to an applied force or stress or that an applied voltage may cause a change in the dimension of the material. In various embodiments, the piezoelectric material may be aluminium nitride (AlN), zinc oxide (ZnO), lead zirconate titanate (PZT), quartz (SiO₂), aluminum gallium arsenide (AlGaAs), gallium arsenide (GaAs), silicon carbide (SiC), langasite (LGS), gallium nitride (GaN), lithium tantalate (LiTaO₃), lithium niobate (LiNbO₃), polyvinylidene fluoride (PVDF) or any other materials that exhibit piezoelectricity effect. The piezoelectric material may be provided in the form of a piezoelectric structure incorporating the piezoelectric material. The piezoelectric material or structure may be in the shape of a square, a rectangle or a circle. However, it should be appreciated that the piezoelectric material or structure may be in any shape or form. The term “piezoelectric material” as used hereinafter may refer to a piezoelectric material or a piezoelectric structure incorporating a piezoelectric material.

The term “electrode” may mean an electrical conductor through which an electrical current may flow. In various embodiments, the surface acoustic wave resonator may include a pair of electrodes making up the interdigital transducer (IDT). Each of the pair of electrodes may include a plurality of teeth. The pair of electrodes may be arranged in an interdigitated pattern or structure to provide one dimensional propagation of the surface acoustic waves. In various embodiments, the pair of electrodes may include a single-beam configuration or a double-beam configuration. In the case of the single-beam configuration, each tooth of the plurality of teeth of one electrode is alternatively arranged with each tooth of the plurality of teeth of the other electrode. In the case of the double-beam configuration, a pair of teeth of the plurality of teeth of one electrode is alternatively arranged with a pair of teeth of the plurality of teeth of the other electrode. In various embodiments, each of the pair of electrodes may be combed-shaped. However, it should be appreciated that each electrode or the pair of electrodes may take other forms or patterns. For example, in further embodiments, electrodes having substantially concentric-circular patterns may be provided to provide two dimensional propagation of the surface acoustic waves. The concentric-circular patterns may have a single-beam configuration or a double-beam configuration. Other types of electrode patterns that may excite and maintain substantially the uniformity of the wave propagation may also be provided. In various embodiments, the surface acoustic wave generated may have a pattern that substantially resembles or substantially similar to the pattern or structure or arrangement of the electrodes, such as that arranged in the interdigitated pattern or the concentric-circular pattern.

In various embodiments, each electrode of the pair of electrodes may excite a surface acoustic wave to propagate through or on the surface of the piezoelectric material. In further embodiments, the pair of electrodes may excite a surface acoustic wave to propagate through or on the surface of the piezoelectric material. Additionally, the pair of electrodes may be used for sensing or detecting purposes, such as picking up a signal. For example, the surface acoustic wave excited on the piezoelectric material may be sensed or detected as an electrical signal due to the piezoelectric effect.

In various embodiments, the piezoelectric material may be electrically coupled to the pair of electrodes such that each of the pair of electrodes or the pair of electrodes may excite or generate a surface acoustic wave to propagate through or on the surface of the piezoelectric material. In this context, the term “electrically coupled” may mean that the piezoelectric material is in electrical communication with the pair of electrodes such that an electrical current flowing through the pair of electrodes (or an electrical voltage applied to the pair of electrodes) may cause an effect on the piezoelectric material, for example generating a surface acoustic wave to propagate through, or on the surface of the piezoelectric material. In various embodiments, a potential (eg. a voltage) applied to the pair of electrodes may cause deformation of the piezoelectric material. The deformation induced represents excitation or source of the surface acoustic wave, which may propagate through or on the surface of the piezoelectric material. In various embodiments, the resonant frequency of the SAW resonators may be determined based on the geometrical arrangement of the electrode or the pair of electrodes making up the IDT, as well as the natural resonance mode shapes of the entire structure of the resonators.

The term “free boundary”may mean a free edge or free edges on the surfaces of a material. A material having free boundary would be substantially surrounded by air on the surfaces (ie free edges) of the material. In other words, the surfaces of the material may not be in contact with another material. In various embodiments, a material may have surfaces that are not free edges, in addition to surfaces that are free edges.

The term “floating”, “levitate”, “levitating” or “levitation” may mean that a material may be arranged at a distance from a surface of another material such that a gap, such as an air gap, may be present between the two materials.

In various embodiments, a surface acoustic wave resonator is provided. The surface acoustic wave resonator may include a first electrode and a second electrode arranged in a first layer; a piezoelectric structure formed in a second layer adjacent to the first layer; wherein the piezoelectric structure is electrically coupled to the first electrode and the second electrode; and wherein the piezoelectric structure is formed only in the second layer.

In various embodiments, a surface acoustic wave resonator is provided. The surface acoustic wave resonator may include a first electrode and a second electrode; a piezoelectric structure electrically coupled to the first electrode and the second electrode; and wherein the piezoelectric structure is configured to levitate on a substrate of the surface acoustic wave resonator.

In various embodiments, a method for manufacturing a surface acoustic wave resonator is provided. The method may include forming a first electrode and a second electrode arranged in a first layer; and forming a second layer comprising a piezoelectric material adjacent to the first layer such that the piezoelectric material is electrically coupled to the first electrode and the second electrode and the first layer is free of the piezoelectric material.

Various embodiments may, provide a floating surface acoustic wave (FSAW) resonator or device that provides levitation of the piezoelectric material and its corresponding electrodes or excitation electrodes to reduce the loss of energy through the substrate where the FSAW resonator is formed therein or thereon and to provide free edges substantially around the piezoelectric material, thereby eliminating the need for reflectors.

Various embodiments may provide a floating surface acoustic wave (FSAW) resonator or device that includes one metal layer, one piezoelectric material layer and one sacrificial layer. The sacrificial layer may be removed during the fabrication process to levitate the piezoelectric material to realize the floating device.

In order that the invention may be readily understood and put into practical effect, particular embodiments will now be described by way of the following non-limiting examples.

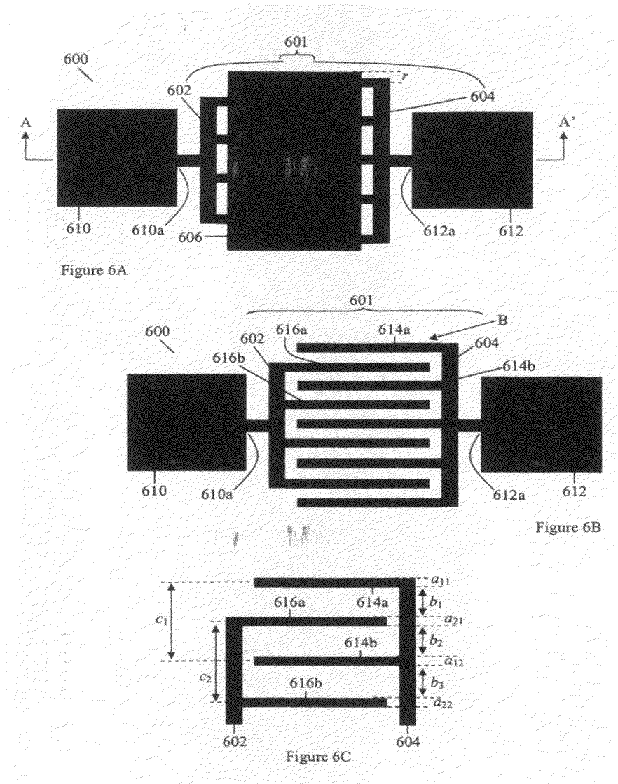

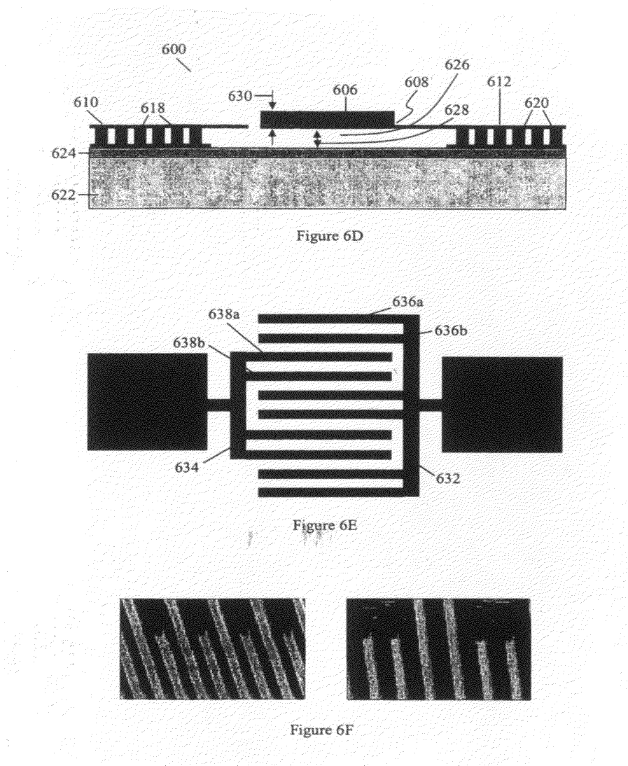

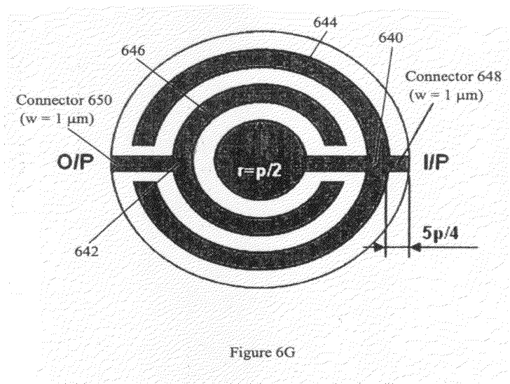

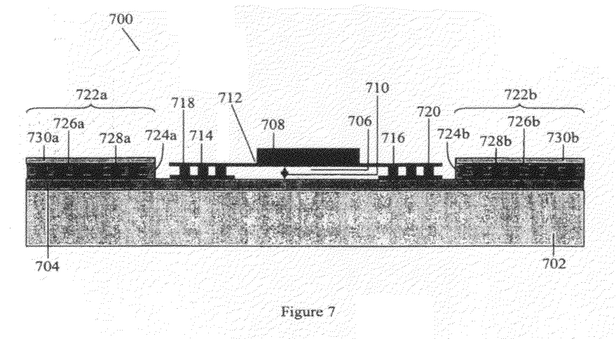

FIGS. 6A-6D show schematic views of a surface acoustic wave resonator 600, according to various embodiments. For illustration and clarity purposes, the substrate 622 and the dielectric layer 624 (as illustrated in FIG. 6D) are not shown in FIGS. 6A, 6B and 6C.

FIG. 6A shows a top view of the surface acoustic wave resonator 600, according to various embodiments. The surface acoustic wave resonator 600 includes an interdigital transducer (IDT) 601 and a piezoelectric material 606, on and over the top surface 608 (FIG. 6D) of the IDT 601. The IDT 601 and the piezoelectric material 606 may form a resonating microstructure. The piezoelectric material 606 may be aluminium nitride (AlN).

In various embodiments, the IDT 601 may include a pair of electrodes 602, 604. The IDT 601, including the pair of electrodes 602, 604, may be made of metal. The metal may be aluminium. In further embodiments, the metal may be platinum, gold, molybdenum, titanium or tungsten.

The IDT 601 may define the resonant frequency of the surface acoustic wave resonator 600, which may be approximated using the equation v=fλ, where λ is the wavelength, f is the resonant frequency and v is the phase velocity of the surface acoustic wave generated. In various embodiments, the phase velocity, v, may depend on the density and thickness of the metal IDT and the piezoelectric material. The wavelength, λ, of the surface acoustic wave for a particular frequency, f, may be identified, when the phase velocity, v, has been determined.

In various embodiments, for a resonator employing aluminium nitride, with a density of 1325 kg/cm³ and a thickness of about 1 μm, as the piezoelectric material and aluminium, with a density of about 2300 kg/m³ and a thickness of about 1000 Å (0.1 μm), for the IDT, the phase velocity, v, of the surface acoustic wave may be approximately 5800 m/s.

In various embodiments, CMOS IC processing with a critical dimension (CD) of about 0.18 μm may provide an SAW resonator for operation at frequencies of up to about 8 GHz.

In various embodiments, the piezoelectric material 606 may cover substantially the top surface 608 of the IDT 601 or alternatively the top surface 608 of the pair of electrodes 602, 604. Accordingly, the surface acoustic wave resonator 600 may have a structure where each of the pair of electrodes 602, 604, is arranged in a first layer and the piezoelectric material 606 is formed in a second layer adjacent to the first layer. In various embodiments, the first layer including the pair of electrodes 602, 604, may be free of the piezoelectric material 606. In further embodiments, the piezoelectric material 606 may be formed only in the second layer.

In various embodiments, the piezoelectric material 606 and the pair of electrodes 602, 604, may be arranged such that the piezoelectric material 606 is electrically coupled to each of the electrodes 602, 604. In various embodiments, each of the electrodes 602, 604, may excite a surface acoustic wave to propagate through or on the surface of the piezoelectric material 606. In further embodiments, the pair of electrodes 602, 604, may excite a surface acoustic wave to propagate through or on the surface of the piezoelectric material 606.

In various embodiments, the piezoelectric material 606 may have a length of about 1 mm and a width of about 1 mm. In addition, the piezoelectric material 606 may have a thickness in the range of about 0.1 μm to about 3 μm, depending on the deposition process used. Therefore, the piezoelectric material 606 may, for example, have a thickness in the range of about 0.1 μm to about 2 μm, about 0.1 μm to about 1 μm or about 1 μm to about 3 μm or a thickness of about 0.1 μm, about 0.5 μm, about 1 about 1.5 μm, about 2 μm or about 3 μm. In further embodiments, the piezoelectric material 606 may have any length and width, up to the length and width of the wafer used for the fabrication of the SAW resonators of various embodiments. In other words, the piezoelectric material 606 may have any lengths and widths, limited only by the size of the wafer used for fabrication.

In various embodiments, the distance between the edge of the piezoelectric material 606 and the centre of the extreme tooth of the electrode 604 may have the dimension r. The dimension r, may be determined from the equation [r=nλ+(λ/2), where n is a positive integer (ie n=1, 2, 3, . . . ) and λ is the wavelength of the acoustic surface wave to be formed or excited by the electrodes 602, 604.

In various embodiments, the surface acoustic wave resonator 600 may further include supports or supporting anchors 610, 612. The supporting anchors 610, 612, may be micro-supporting anchor structures. The supporting anchor 610 may be coupled to the electrode 602 while the supporting anchor 612 may be coupled to the electrode 604, such that the electrode 602 may be fixed or attached to the supporting anchor 610 at the point 610a while the electrode 604 may be fixed or attached to the supporting anchor 612 at the point 612a.

In various embodiments, the supporting anchors 610, 612, may have a length in the range of about 1 μm to about 200 μm, for example a range of about 1 μm to about 100 μm, about 1 μm to about 50 μm or about 50 μm to about 200 μm, such that the length may be about 1 μm, about 10 μm, about 50 μm, about 100 μm or about 200 μm. In various embodiments, the supporting anchors 610, 612, may have a width in the range of about 1 μm to about 10 μm, for example a range of about 1 μm to about 5 μm or a range of about 5 μm to about 10 μm, such that the width may be about 1 μm, about 2 μm, about 5 μm or about 10 μm. In various embodiments, the supporting anchors 610, 612, may have a thickness in the range of about 4000 Å (Angstrom) (ie. 0.4 μm) to about 1.0 μm, for example a range of about 0.4 μm to about 0.8 μm, about 0.4 μm to about 0.6 μm or about 0.5 μm to about 1.0 μm, such that the thickness may be about 0.4 μm, about 0.5 μm, about 0.6 μm, about 0.8 μm about 1.0 μm. In various embodiments, the supporting anchors 610, 612, may be made of metal. The metal may be aluminium. In further embodiments, the metal may be platinum, gold, molybdenum, titanium or tungsten.

In various embodiments, the pair of electrodes 602, 604, and the supporting anchors 610, 612, may either be made of the same material (ie. the same metal) or made of different metals.

FIG. 6B shows a top view of the surface acoustic wave resonator 600 according to various embodiments, with the piezoelectric material 606 removed to illustrate the structures or patterns of each of the electrodes 602, 604.

In various embodiments, each of the electrodes 602, 604, may be in the shape of a comb. The comb-shaped electrode 604 may include a plurality of teeth, for example as represented by 614a, 614b, and the comb-shaped electrode 602 may include a plurality of teeth, for example as represented by 616a, 616b.

In various embodiments, the electrodes 602, 604, may be arranged in an interdigitated pattern or structure, and in a single-beam configuration, where each of the teeth 614a, 614b, of the electrode 604 is alternatively arranged with each of the teeth 616a, 616b, of the electrode 602.

FIG. 6C shows an expanded partial top view of the pair of electrodes 602, 604, taken towards the end B of the pair of electrodes 602, 604, of FIG. 6B.

In various embodiments, the tooth 614a of electrode 604 may have the width a₁₁ and the tooth 614b of electrode 604 may have the width a₁₂ while the tooth 616a of electrode 602 may have the width a₂₁ and the tooth 616b of electrode 602 may have the width a₂₂. The tooth widths, a₁₁, a₁₂, a₂₁ and a₂₂, may be of the same or substantially similar dimension.

In various embodiments, the spacing between the teeth 614a and 616a may have the dimension b₁, the spacing between the teeth 616a and 614b may have the dimension b₂ and the spacing between the: teeth 614b and 616b may have the dimension b₃. The spacings, b₁, b₂ and b₃, may be of the same or substantially similar dimension.

In various embodiments, the distance from the center of the tooth 614a to the center of the tooth 614b of the electrode 604 may have the dimension c₁ and the distance from the center of the tooth 616a to the center of the tooth 616b of the electrode 602 may have the dimension c₂. The distances, c₁ and c₂, may be of the same or substantially similar dimension. In various embodiments, the distance (eg. c₁) between the centre of two successive teeth (eg. 614a and 614b) of an electrode (eg. 604) may correspond to the wavelength, λ, of the acoustic surface wave to be formed or excited by the electrode (eg. 604).

In various embodiments, symmetrical widths, spacings or distances may be provided such that a₁₁=a₁₂=a₂₁=a₂₂, b₁=b₂=b₃ and c₁=c₂. In addition, various embodiments may provide that a=₁₁=a₁₂=a₂₁=a₂₂=b₁=b₂=b₃=1 μm and c₁=c₂=4 μm, resulting in a resonant frequency of about 1.323 GHz.

While descriptions and dimensions have been provided with respect to the teeth 614a, 614b, 616a, 616b, it should be appreciated that the electrodes 602, 604, may have any number of teeth and similar descriptions and dimensions may apply to these other teeth. In various embodiments, each of the electrodes 602, 604, may have a plurality of teeth in the range of about 10 to 500 teeth, for example a range of about 10 to 300 teeth, a range of about 10 to 200 teeth, a range of about 10 to 100 teeth, a range of about 50 to 500 teeth, a range of about 100 to 500 teeth or a range of about 100 to 300 teeth, such that each of the electrodes 602, 604, may have 10 teeth, 20 teeth; 30 teeth, 50 teeth, 80 teeth, 100 teeth, 200 teeth, 300 teeth, 400 teeth or 500 teeth. However, it should be appreciated that each of the electrodes 602, 604, may have any number of teeth, depending on the requirement of impedance for the SAW resonators. Therefore, the number of teeth may be varied in order to tune the impedance of the SAW resonators of various embodiments.

FIG. 6D shows a cross-sectional view of the surface acoustic wave resonator 600 taken along the line A-A′ of FIG. 6A. As shown in FIG. 6D, the supporting anchor 610 includes a plurality of columnar pillars 618 and the supporting anchor 612 includes a plurality of columnar pillars 620. The plurality of columnar pillars 618 of the supporting anchor 610 and the plurality of columnar pillars 620 of the supporting anchor 612 may be arranged in a uniform pattern. In further embodiments, the plurality of columnar pillars 618 and the plurality of columnar pillars 620 may be arranged in a random pattern. Each pillar of the plurality of columnar pillars 618 and the plurality of columnar pillars 620 may have the dimensions of 0.8 μm×0.8 μm and a height in the range of about 0.4 μm to about 1.0 μm, for example, when based on CMOS 0.18 μm technology. In various embodiments, the plurality of columnar pillars 618, 620, are provided as a result of the interconnection design rules as known in the art, for CMOS processes. The interconnection design rules may be defined, for example, by the CMOS foundries based on the technology node provided by the foundries. In further embodiments, where the design rules may be waived, bulk supporting anchors (ie. without columnar pillars) may be provided.

In various embodiments, the surface acoustic wave resonator 600 may be provided on a substrate 622 including a layer of dielectric 624 such that a gap 626 is present between the substrate 622 with the dielectric layer 624 and the piezoelectric material 606 with the electrodes. Accordingly, the surface acoustic wave resonator 600 may be a floating surface acoustic wave (FSAW) resonator that provides levitation of the piezoelectric material 606 and the electrodes on or above the substrate 622. As shown in FIG. 6D, the piezoelectric material 606 may have free boundary or free edges around the piezoelectric material 606. In various embodiments, the gap 626 may be an air gap. The gap 626 may have a distance, as represented by the arrow 628, in the range of about 1 μm to about 10 μm, for example a range of about 1 μm to about 8 μm, a range of about 1 μm to about 5 μm or a range of about 5 μm to about 10 μm, such that the distance of the gap 626 may be about 1 μm, about 2 μm, about 5 μm or about 10 μm.

In various embodiments, the substrate 622 may be silicon, for example an 8-inch silicon wafer with a thickness of about 725 μm, while the dielectric layer 624 may be a layer of oxide or nitride. The dielectric layer 624 may be a layer of silicon nitride (Si₃N₄). In further embodiments, the dielectric layer 624 may be a layer of silicon oxide or alumina. The dielectric layer 624 may have a thickness of about 1 μm.

In various embodiments, the material used for the dielectric layer 624 may depend on the material used for the sacrificial layer. For example, where the sacrificial layer is amorphous silicon (a-Si), the dielectric layer 624 may be silicon nitride or silicon oxide. Where the sacrificial layer is silicon oxide, the dielectric layer 624 may be alumina.

In various embodiments, the thickness of the electrodes may be approximately 1000 Å (Angstrom) (ie. 0.1 μm) to 1.0 μm, for example approximately 0.1 μm to 0.5 μm or approximately 0.5 μm to 1.0 μm, such that the sum of the thickness of the piezoelectric material 606 and the electrodes, as represented by the arrow 630, may be approximately 6000 Å (ie. 0.6 μm) to 2.0 μm, for example approximately 0.6 μm to 1.5 μm, approximately 0.6 μm to 1.0 μm or approximately 1.0 μm to 2.0 μm.

In various embodiments, the thickness of the electrodes may be about 0.1 μm, about 0.2 μm, about 0.5 μm, about 0.8 μm or about 1.0 μm. In various embodiments, the sum of the thickness of the piezelectric material 606 and the electrodes, as represented by the arrow 630, may be about 0.6 μm, about 0.8 μm, about 1.0 μm, about 1.2 μm, about 1.5 μm or about 2.0 μm.

FIG. 6E shows a schematic top view of a surface acoustic wave resonator, with the piezoelectric material removed to illustrate the structures or patterns of the electrodes 632, 634, of further embodiments. The pair of electrodes 632, 634, may be combed-shaped and may be arranged in an interdigitated pattern or structure, and in a double-beam configuration, where a pair of teeth 636a, 636b, of the electrode 632 is alternatively arranged with a pair of the teeth 638a, 638b, of the electrode 634. Further pairs of teeth of the electrode 632 may be alternatively arranged with further pairs of teeth of the electrode 634.

FIG. 6F shows SEM images of electrodes of the surface acoustic wave resonators, according to various embodiments, illustrating the single-beam configuration (left image) and the double-beam configuration (right image).

FIG. 6G shows a schematic top view of a pair of electrodes 640, 642, with a concentric-circular pattern, according to one embodiment. The pair of electrodes 640, 642, may be arranged in a single-beam configuration, where each of the teeth, for example 644, of the electrode 640 is alternatively arranged with each of the teeth, for example 646, of the electrode 642. In further embodiments, the pair of electrodes may be arranged in a double-beam configuration. In various embodiments, the connectors 648, 650, connected to the electrodes 640, 642, respectively, may be connected to the respective supporting anchors (not shown). The connectors 640, 642, may have a width of about 1 μm. In various embodiments, the symbol p represents a design parameter and it should be appreciated that it may have any value, depending on the requirements of the pair of electrodes 640, 642, and the surface acoustic wave resonator. In one embodiment, p may have a value of about 1.08 μm.

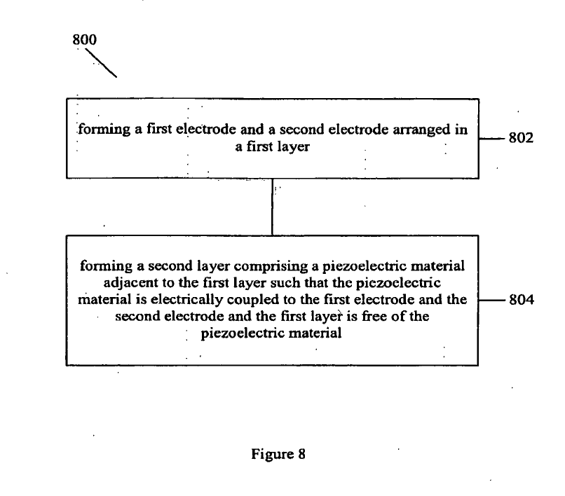

FIG. 7 shows a cross-sectional view of a surface acoustic wave resonator 700, according to various embodiments. The surface acoustic wave resonator 700 may be provided on a substrate 702 including a layer of dielectric 704 such that a gap 706 may be present between the substrate 702 and the piezoelectric material 708. Accordingly, the surface acoustic wave resonator 700 may be a floating surface acoustic wave (FSAW) resonator that provides levitation of the piezoelectric material 708 on or above the substrate 702. As shown in FIG. 7, the piezoelectric material 708 may have free boundary or free edges around the piezoelectric material 708.

In various embodiments, the substrate 702 may be silicon while the dielectric layer 704 may be a layer of oxide or nitride. The piezoelectric material 708 may be aluminium nitride (AlN). In various embodiments, the piezoelectric material 708 may have a length of about 1 mm and a width of about 1 mm. In addition, the piezoelectric material 708 may have a thickness in the range of about 0.1 μm to about 3 μm, depending on the deposition process used. Therefore, the piezoelectric material 708 may, for example, have a thickness in the range of about 0.1 μm to about 2 μm, about 0.1 μm to about 1 μm or about 1 μm to about 3 μm or a thickness of about 0.1 μm, about 0.5 μm, about 1 μm, about 1.5 μm, about 2 μm or about 3 μm. In further embodiments, the piezoelectric material 708 may have any length and width, up to the length and width of the wafer used for the fabrication of the SAW resonators of various embodiments. In other words, the piezoelectric material 708 may have any lengths and widths, limited only by the size of the wafer used for fabrication.

In various embodiments, the gap 706 may be an air gap. The gap 706 may have a distance, as represented by the arrow 710, of approximately 1 μm to about 10 μm, for example a range of about 1 μm to about 8 μm, a range of about 1 μm to about 5 μm or a range of about 5 μm to about 10 μm, such that the distance of the gap 706 may be about 1 μm, about 2 μm, about 5 μm or about 10 μm.

The surface acoustic wave resonator 700 may include an interdigital transducer (IDT) 712 where the piezoelectric material 708 may be positioned on and over the top surface of the IDT 712. The IDT 712 and the piezoelectric material 708 may form a resonating microstructure. As illustrated in FIG. 7, the IDT 712 may be configured to levitate on or above the substrate 702.

In various embodiments, the IDT 712 may include a pair of electrodes. The pair of electrodes may be arranged in an interdigitated pattern, similar to the embodiments illustrated in FIGS. 6B and 6C or FIG. 6E or may be arranged in a concentric-circular pattern similar to the embodiment of FIG. 6G. The IDT 712, including the pair of electrodes may be made of metal. The metal may be aluminium. In further embodiments, the metal may be platinum, gold, molybdenum, titanium or tungsten.

In various embodiments, the piezoelectric structure 708 may cover substantially the top surface of the IDT 712 or alternatively the top surface of the pair of electrodes of the IDT 712. Accordingly, the surface acoustic wave resonator 700 may have a structure where the IDT 712 or each of the pair of the electrodes of the IDT 712 is arranged in a first layer and the piezoelectric material 708 is formed in a second layer adjacent to the first layer. In various embodiments, the first layer including the pair of electrodes may be free of the piezoelectric material 708. In further embodiments, the piezoelectric material 708 may be formed only in the second layer.

In various embodiments, the piezoelectric material 708 and the pair of electrodes of the IDT 712 may be arranged such that the piezoelectric material 708 is electrically coupled to each of the electrodes. In various embodiments, each of the electrodes may excite a surface acoustic wave to propagate through or on the surface of the piezoelectric material 708. In further embodiments, the pair of electrodes may excite a surface acoustic wave to propagate through or on the surface of the piezoelectric material 708.

In various embodiments, the surface acoustic wave resonator 700 may further include supporting anchors 714, 716. The supporting anchors 714, 716, may be micro-supporting anchor structures. The supporting anchors 714, 716, may be coupled respectively to each of the pair of electrodes, such that each of the pair of electrodes may be fixed or attached to the respective supporting anchors 714, 716. In various embodiments, the supporting anchors 714, 716, may be made of metal. The metal may be aluminium. In further embodiments, the metal may be platinum, gold, molybdenum, titanium or tungsten.

In various embodiments, the IDT 712 and the supporting anchors 714, 716, may either be made of the same material (ie. the same metal) or made of different metals.

In various embodiments, the supporting anchor 714 may include a plurality of columnar pillars 718 and the supporting anchor 716 may include a plurality of columnar pillars 720. The plurality of columnar pillars 718 and the plurality of columnar pillars 720 may be arranged in a uniform pattern. In further embodiments, the plurality of columnar pillars 718 and the plurality of columnar pillars 720 may be arranged in a random pattern.

In various embodiments, the surface acoustic wave resonator 700 may further include structures 722a, 722b, on opposite sides of the piezoelectric material 708 and the IDT 712. Each of the structures 722a, 722b, may include a dielectric layer 724a, 724b, including a corresponding metal structure 726a, 726b, formed therein. The dielectric layer 724a, 724b, may be a layer of oxide or nitride. Each of the metal structures 726a, 726b, may include a corresponding plurality of columnar pillars 728a, 728b. The surface acoustic wave resonator 700 may further include a layer of silicon nitride (Si₃N₄) 730a, 730b, on top of the respective dielectric layer 724a, 724b. In various embodiments, the structures 722a, 722b, may serve as metal routing outside of the resonating microstructure and may include a protective layer (ie. the layer of Si₃N₄ 730a, 730b) to preserve or protect the layers beneath the layer of Si₃N₄ 730a, 730b, or the structures 722a, 722b, during release of the resonating microstructure during the fabrication process.

In various embodiments, the thickness of the dielectric layer 724a, 724b, may be about 2 μm to about 3 μm, for example a range of about 2 μm to about 2.5 μm or a range of about 2.5 μm to about 3 μm, such that the thickness may be about 2 μm, about 2.5 μm or about 3 μm. In various embodiments, the thickness of the layer of Si₃N₄ 730a, 730b, may be about 0.5 μm to about 1.5 μm, for example a range of about 0.5 μm to about 1 μm or a range of about 1 μm to about 1.5 μ, such that the thickness may be about 0.5 μm, about 1 μm or about 1.5 μm.

It should be appreciated that the dimensions of like or substantially similar structures or configurations present in the embodiments of FIGS. 6A-6G that are correspondingly present in the embodiment of FIG. 7 may have similar or substantially similar dimensions. In addition, any features or structures or any alternative features to a structure or configuration as described for the embodiments of FIGS. 6A-6G may be applicable to a similar corresponding feature or structure for the embodiment of FIG. 7.

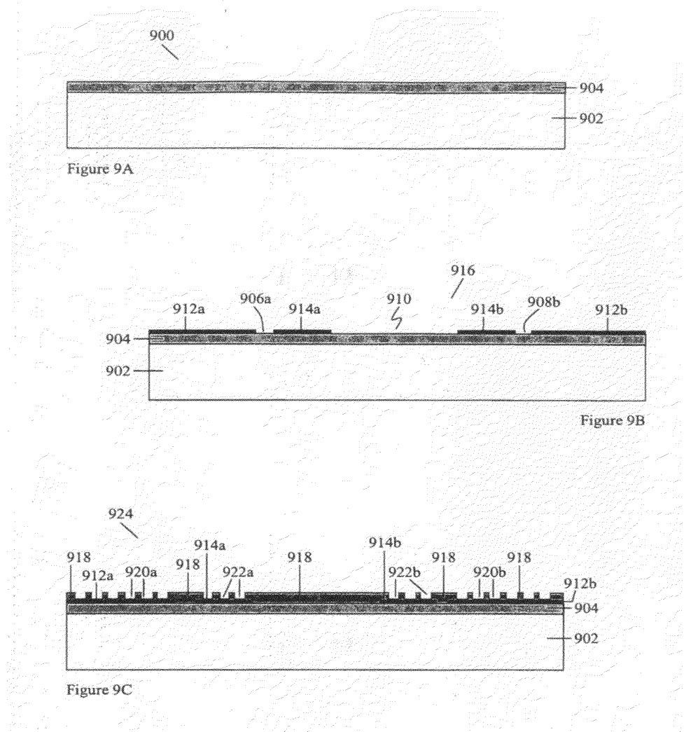

FIG. 8 shows a flow: chart 800 illustrating a method of forming a surface acoustic wave resonator, according to various embodiments.

At 802, a first electrode and a second electrode arranged in a first layer are formed.

At 804, a second layer comprising a piezoelectric material is formed adjacent to the first layer such that the piezoelectric material is electrically coupled to the first electrode and the second electrode and the first layer is free of the piezoelectric material.

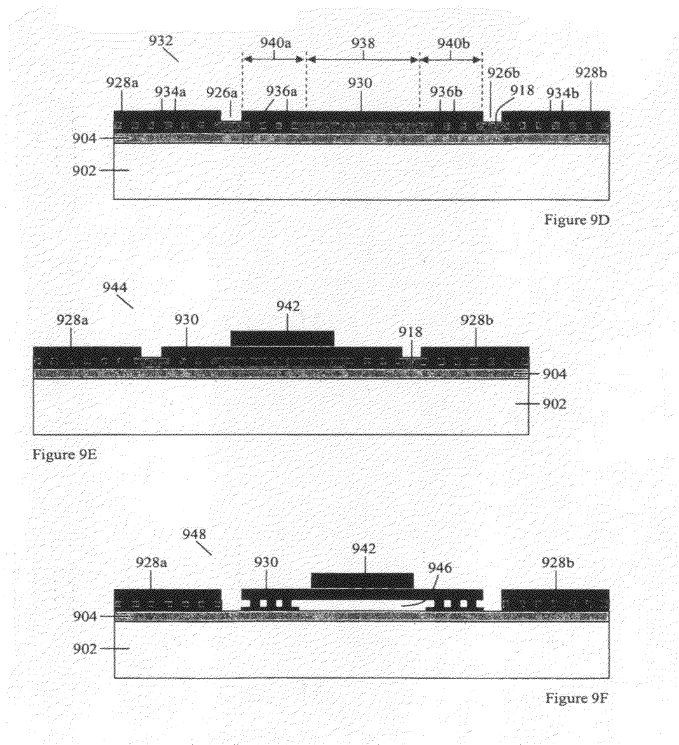

FIGS. 9A to 9F show cross-sectional views of a fabrication process to manufacture a surface acoustic wave resonator, according to various embodiments.

FIG. 9A shows a structure 900 that may be used for the fabrication of a surface acoustic wave resonator of various embodiments. A substrate 902 may be provided. The substrate 902 may be a silicon substrate, for example an 8-inch silicon wafer with a thickness of about 725 μm. Low-pressure chemical vapor deposition (LPCVD) may be carried out to deposit a layer of relatively low stress nitride 904 of a thickness of about 1 μm. The layer 904 may be a layer of silicon nitride (Si₃N₄).

The structure 900 may then be subjected to a sputtering deposition process to deposit a layer of aluminium of a thickness of about 4000 Å (4000 angstrom). Selective patterning using a first mask and a reactive ion etching (RIE) process are carried out to create openings 906a, 908b, 910, to partially expose the nitride layer 904 in order to define aluminium sections 912a, 912b, 914a, 914b, of the deposited aluminium layer. FIG. 9B shows the structure 916 that may be formed.

Plasma-enhanced chemical vapor deposition (PECVD) is then carried out on the structure 916 to deposit a layer of silicon dioxide (SiO₂) 918 of a thickness of about 8000 Å (8000 angstrom). Selective patterning using a second mask and a reactive ion etching (RIE) process are performed to create pluralities of via holes 920a, 920b, 922a, 922b, in the layer of silicon dioxide (SiO₂) 918 at the aluminium sections 912a, 912b, 914a, 914b, respectively. FIG. 9C shows the structure 924 that may be formed. In various embodiments, the pluralities of via holes 920a, 920b, 922a, 922b, may have a diameter or a width of about 0.5 μm to about 0.8 μm, such that the diameter may be about 0.5 μm, about 0.6 μm, about 0.7 μm or about 0.8 μm. However, it should be appreciated that the pluralities of via holes 920a, 920b, 922a, 922b, may have any diameter, depending on the lithography process used.

The structure 924 may then be subjected to an aluminium sputtering deposition process to fill the pluralities of via holes 920a, 920b, 922a, 922b, and to deposit a layer of aluminium of a thickness of about 1 μm. Selective patterning using a third mask and a reactive ion etching (RIE) process are carried out to create openings 926a, 926b, to partially expose the SiO₂ layer 918 in order to define aluminium structures 928a, 928b, 930. FIG. 9D shows the structure 932 that may be formed. The aluminium structure 928a includes the aluminium section 912a (FIG. 9C) and a plurality of columnar pillars 934a formed in the plurality of via holes 920a (FIG. 9C). The aluminium structure 928b includes the aluminium section 912b (FIG. 9C) and a plurality of columnar pillars 934b formed in the plurality of via holes 920b (FIG. 9C). The aluminium structure 930 includes the aluminium sections 914a, 914b, (FIG. 9C) and pluralities of columnar pillars 936a, 936b, formed in the pluralities of via holes 922a, 922b (FIG. 9C).

Selective patterning and etching may then be carried out on a substantially central portion, as represented by the arrow 938, of the aluminium structure 930 to define the electrodes that make up the interdigital transducer (IDT). The electrodes may be of the embodiments shown in FIGS. 6B and 6C or FIG. 6E or FIG. 6G. The portions of the aluminium structure 930 represented by the arrows 940a and 940b indicate the portions where the supporting anchors may be positioned.

Physical vapour deposition (PVD) is then carried out on the structure 932 to deposit a layer of aluminium nitride (AlN) of a thickness of about 1.5 μm. Selective patterning using a fourth mask and a subsequent reactive ion etching (ME) may be carried out to fabricate the piezoelectric material 942, to form the structure 944 as shown in FIG. 9E. In various embodiments, the thickness of the layer of AlN may be in the range of about 0.1 μm to about 3 μm, for example a range of about 0.1 μm to about 2 μm, a range of about 0.1 μm to about 1 μm or a range of about 1 μm to about 3 μm, such that the thickness may be about 0.1 μm, about 0.5 μm, about 1 μm, about 1.5 μm, about 2 μm or about 3 μm.

Buffered oxide etch (BOE), for example in the form of buffered hydrofluoric acid (HF) vapour, may then be used to etch the SiO₂ layer 918, except those within the aluminium structures 928a, 928b, to create an air gap 946 to provide a levitation of the piezoelectric material 942 on or above the substrate 902 and the nitride layer 904. The air gap 946 formed also provides a levitation of the IDT. FIG. 9F shows the final structure 948 formed. Hot isopropanol (IPA) may then be used to dry the structure 948.

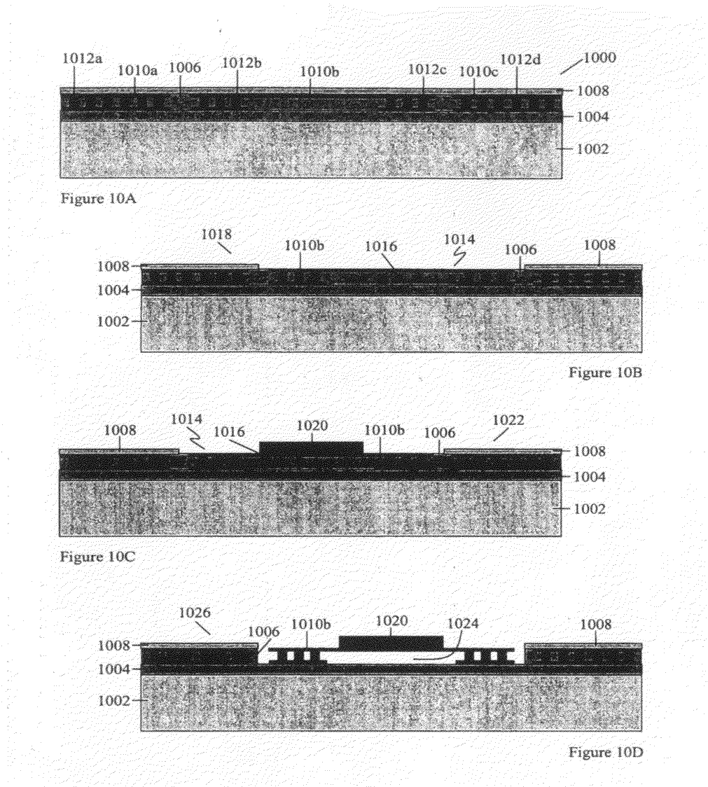

FIGS. 10A to 10D show cross-sectional views of a fabrication process to manufacture a surface acoustic wave resonator, according to various embodiments.

FIG. 10A shows a CMOS IC wafer 1000 that may be fabricated by a foundry using IC processes. The IC wafer 1000 may include a substrate 1002, a dielectric layer 1004, a sacrificial layer 1006 and a top layer 1008. In various embodiments, the substrate 1002 may be a silicon substrate, the dielectric layer 1004 may be a layer of oxide or nitride, the sacrificial layer 1006 may be a layer of oxide and the top layer 1008 may be a layer of silicon nitride (Si₃N₄). The sacrificial layer 1006 may include a plurality of metal structures 1010a, 1010b, 1010c, having a plurality of columnar pillars 1012a, 1012b, 1012c, 1012d, formed therein as shown in FIG. 10A. The plurality of metal structures 1010a, 1010b, 1010c, may be made of aluminium

In various embodiments, the thickness of each of the dielectric layer 1004, the sacrificial layer 1006 and the top layer 1008, as fabricated at a CMOS foundry may be in the range of about 1000 Å (0.1 μm) to about 10000 Å (1 μm), for example a range of about 0.1 μm to about 0.8 μm, a range of about 0.1 μm to about 0.4 μm or a range of about 0.4 μm to about 0.8 μm, such that the thickness may be about 0.1 μm, about 0.4 μm, about 0.6 μm, about 0.8 μm or about 1 μm. In further embodiments, a thick metal process as known in the art may be used so that the thickness of each of the dielectric layer 1004, the sacrificial layer 1006 and the top layer 1008 may be up to about 3 μm, for example a thickness of about 1.5 μm, about 2 μm, about 2.5 μm or about 3 μm.

The IC wafer 1000 may be subjected to selective etching to partially etch the top layer 1008 to create an opening 1014 that exposes substantially the top surface 1016 of the metal structure 1010b to form the structure 1018, as shown in FIG. 10B. In various embodiments, reactive ion etching (RIE), with etchant gases tetrafluoromethane (CF₄) or trifluoromethane (CHF₃) mixed with oxygen (O₂) or argon (Ar), may be used to perform the selective etching. In further embodiments, optionally or alternatively, this etching step may not be required if etching has been carried out at the CMOS foundry. In other words, the embodiment of FIG. 10B may be fabricated by a CMOS foundry.

Selective patterning and etching may then be carried out on a substantially central portion of the metal structure 1010b to define the electrodes that make up the interdigital transducer (IDT). The electrodes may be of the embodiments shown in FIGS. 6B and 6C or FIG. 6E or FIG. 6G. In further embodiments, optionally or alternatively, this patterning and etching step may not be required if this step has been carried out at the CMOS foundry. In other words, the electrodes may be pre-defined during the CMOS process at the CMOS foundry.

Physical vapour deposition (PVD) is then carried out on the structure 1018 to deposit a layer of aluminium nitride (AlN). In various embodiments, the thickness of the layer of AlN may be in the range of about 0.1 μm to about 3 μm, for example a range of about 0.1 μm to about 2 μm, a range of about 0.1 μm to about 1 μm or a range of about 1 μm to about 3 μm, such that the thickness may be about 0.1 μm, about 0.5 μm, about 1 μm, about 1.5 μm, about 2 μm or about 3 μm. Selective patterning using a mask and a subsequent reactive ion etching (RIE) may be carried out to fabricate the piezoelectric material 1020, to form the structure 1022 as shown in FIG. 10C.

Buffered oxide etch (BOE), for example in the form of buffered hydrofluoric acid (HF) vapour, may then be used to etch the sacrificial layer 1006 through the opening 1014 to create an air gap 1024 to provide a levitation of the piezoelectric material 1020 on or above the substrate 1002 and the dielectric layer 1004, to form the final structure 1026 of FIG. 10D. Hot isopropanol (IPA) may then be used to dry the structure 1026.

Various embodiments may provide a floating surface acoustic wave (FSAW) resonator or device that includes one metal layer, one piezoelectric material layer and one sacrificial layer. The sacrificial layer may be removed during the fabrication process to levitate the piezoelectric material to realize the floating device.

Various embodiments may provide for integration with IC processes, where the metal layer may correspond to the metal layers or the conducting layers in the IC process while the sacrificial layer may correspond to the silicon oxide layer in the IC process. Patterning of the piezoelectric material and release of the resonating microstructure may be performed via a single mask in a post processing operation to achieve integration with IC while also reducing cost.

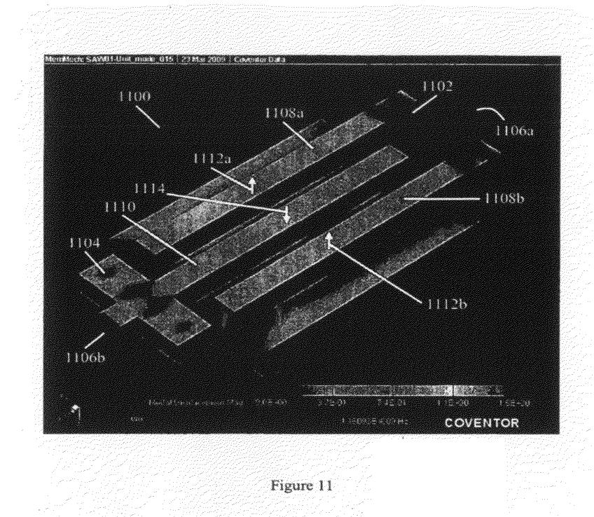

FIG. 11 shows the simulation data of a surface acoustic wave resonator of various embodiments. The simulation data was generated using the Coventor software to demonstrate the operation of the reflector-less floating surface acoustic wave (FSAW) resonator. FIG. 11 shows the structure 1100 used for the simulation process. The structure 1100 includes an actuation electrode 1102 and a sensing electrode 1104, which are fixed at the point 1106a and 1106b, respectively. The actuation electrode 1102 and the sensing electrode 1104 are arranged in an interdigitated pattern where each tooth, for example 1108a and 1108b, of the actuation electrode 1102 is provided alternatively with each tooth, for example 1110, of the sensing electrode 1104. At the resonant frequency, each tooth, for example 1108a and 1108b, of the actuation electrode 1102, may move in a particular direction, for example as represented by the arrows 1112a and 1112b, while each tooth, for example 1110, of the sensing electrode 1104, may move in the opposite direction, for example as represented by the arrow 1114. The structure 1100 occupies an area of approximately 8 μm×17 μm, not including the supporting anchors.

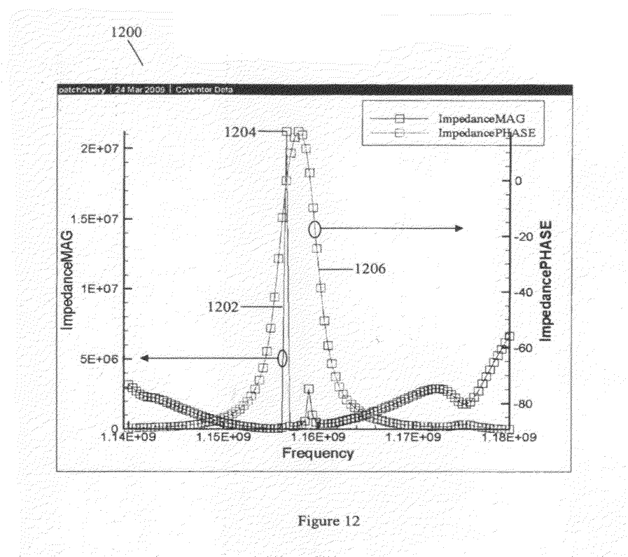

FIG. 12 shows a plot 1200 of the resonant mode shape 1202 with the resonant peak 1204 and the impedance frequency response 1206 for the embodiment of FIG. 11. The results show that the resonant frequency is approximately 1.16 GHz, where the structure 1100 has been configured to excite a surface acoustic wave with a wavelength of about 4 μm. The resonant frequency, may be increased by increasing the phase velocity, for example by reducing the thickness of the electrodes 1102, 1104 (FIG. 11) and increasing the resolution of the lithography process to pattern structures with smaller dimensions.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A surface acoustic wave resonator comprising: a first electrode and a second electrode arranged in a first layer; a piezoelectric material formed in a second layer adjacent to the first layer; wherein the piezoelectric material is electrically coupled to the first electrode and the second electrode; and wherein the first layer is free of the piezoelectric material.

2. The surface acoustic wave resonator according to claim 1, wherein each of the first electrode and the second electrode comprises a plurality of teeth.

3. The surface acoustic wave resonator according to claim 1, wherein the first electrode and the second electrode are arranged in an interdigitated pattern or a concentric-circular pattern.

4. The surface acoustic wave resonator according to claim 2, wherein the first electrode and the second electrode are arranged such that each tooth of the plurality of teeth of the first electrode is alternately arranged with each tooth of the plurality of teeth of the second electrode.

5. The surface acoustic wave resonator according to claim 2, wherein the first electrode and the second electrode are arranged such that a pair of teeth of the plurality of teeth of the first electrode is alternately arranged with a pair of teeth of the plurality of teeth of the second electrode.

6. The surface acoustic wave resonator according to claim 3, wherein the first electrode and the second electrode arranged in the interdigitated pattern are comb-shaped.

7. The surface acoustic wave resonator according to claim 1, further comprising a substrate, wherein the piezoelectric material is configured to levitate on the substrate.

8. The surface acoustic wave resonator according to claim 7, wherein the first electrode and the second electrode are configured to levitate on the substrate.

9. The surface acoustic wave resonator according to claim 1, wherein the piezoelectric material has a free boundary.

10. The surface acoustic wave resonator according to claim 1, wherein the piezoelectric material is aluminium nitride, zinc oxide, lead zirconate titanate, quartz, aluminum gallium arsenide, gallium arsenide, silicon carbide, langasite, gallium nitride, lithium tantalate, lithium niobate or polyvinylidene fluoride.

11. (canceled)

12. The surface acoustic wave resonator according to claim 1, wherein the first electrode is arranged such that it excites a surface acoustic wave in the piezoelectric material.

13. (canceled)

14. The surface acoustic wave resonator according to claim 1, further comprising a first support coupled to the first electrode and a second support coupled to the second electrode.

15. The surface acoustic wave resonator according to claim 1, wherein the first electrode and the second electrode are configured to form an interdigital transducer.

16. A surface acoustic wave resonator comprising:
a first electrode and a second electrode arranged in a first layer;
a piezoelectric structure formed in a second layer adjacent to the first layer;
wherein the piezoelectric structure is electrically coupled to the first electrode and the second electrode; and
wherein the piezoelectric structure is formed only in the second layer.

17. The surface acoustic wave resonator according to claim 16, wherein the first electrode and the second electrode are arranged in an interdigitated pattern or a concentric-circular pattern.

18. The surface acoustic wave resonator according to claim 16, further comprising a substrate, wherein the piezoelectric structure is configured to levitate on the substrate.

19. A surface acoustic wave resonator comprising:
a first electrode and a second electrode;
a piezoelectric structure electrically coupled to the first electrode and the second electrode; and
wherein the piezoelectric structure is configured to levitate on a substrate of the surface acoustic wave resonator.

20. A method for manufacturing a surface acoustic wave resonator comprising:
forming a first electrode and a second electrode arranged in a first layer; and forming a second layer comprising a piezoelectric material adjacent to the first layer such that the piezoelectric material is electrically coupled to the first electrode and the second electrode and the first layer is free of the piezoelectric material.

21. The method according to claim 20, wherein the forming of the second layer comprises depositing the piezoelectric material on the first layer.

22. The method according to claim 20, further comprising levitating the second layer on a substrate of the surface acoustic wave resonator.
